(19) United States
(12) Patent Application Publication
(10) Pub. No.: US 2026/0293110 A1
(43) Pub. Date: Sep. 24, 2026

(54) SEMICONDUCTOR DEVICE AND METHOD FOR FABRICATING THE SAME

(71) Applicant: SK hynix Inc., Gyeonggi-do (KR)

(72) Inventors: Gwang Il JO, Gyeonggi-do (KR); Sung Bin KIM, Gyeonggi-do (KR)

(21) Appl. No.: 19/315,874

(22) Filed: Sep. 2, 2025

(30) Foreign Application Priority Data
Mar. 24, 2025 (KR) 10-2025-0037287

(51) Int. Cl. H10B 12/00; H01L 23/528; H01L 23/532

(52) U.S. Cl. CPC H10B 12/482; H10B 12/315; H10B 12/34; H10W 20/435; H10W 20/4451

(57) ABSTRACT

A semiconductor device and a method of manufacturing the semiconductor device are provided. The semiconductor device includes: a semiconductor substrate; neighboring bit line structures spaced apart from each other over the semiconductor substrate; at least one contact pad formed in the semiconductor substrate between the neighboring bit line structures and having a bottom surface which is lower than a bottom surface of the neighboring bit line structures; and a storage node contact, disposed over the at least one contact pad, contacting the at least one contact pad.

### CROSS-REFERENCE TO RELATED APPLICATIONS

The present application claims priority under 35 U.S. C 119(a) to Korean Patent Application No. 10-2025-0037287, filed on Mar. 24, 2025, which is incorporated herein by reference in its entirety.

### BACKGROUND

### 1. Field

Various embodiments of the present invention relate to a semiconductor device, and more particularly, to a semiconductor device including a contact pad, and a method for fabricating the semiconductor device.

### 2. Description of the Related Art

Recently, as semiconductor devices become more highly integrated the practice of forming buried gate structures in substrates has been utilized to help facilitate this increased integration. Also, bit line contacts are being applied to couple bit lines and substrates to each other.

However, concerns such as leaning (or tilting) may occur due to the narrow line width and height that may be caused when the bit line and the bit line contacts are etched.

### SUMMARY

Embodiments of the present disclosure are directed to a semiconductor device with a reduced difficulty of a process for forming a bit line by forming a storage node contact pad first, and then decreasing the etching height of the bit line.

In accordance with an embodiment of the present disclosure, a semiconductor device includes: a semiconductor substrate; neighboring bit line structures spaced apart from each other over the semiconductor substrate; at least one contact pad formed in the semiconductor substrate between the neighboring bit line structures and having a bottom surface which is lower than a bottom surface of the neighboring bit line structures; and a storage node contact, disposed over the at least one contact pad, contacting the at least one contact pad.

In accordance with another embodiment of the present disclosure, a method for fabricating a semiconductor device includes: providing a semiconductor substrate including an isolation layer and an active region defined by the isolation layer; forming an opening by etching the semiconductor substrate; forming a contact spacer on an inner sidewall of the opening; forming contact pads spaced apart from each other by an isolation dielectric layer, over the contact spacer and the semiconductor substrate in the opening; forming neighboring bit line structures over the active region and the isolation dielectric layer; and forming a storage node contact coupled to one of the contact pads between the neighboring bit line structures.

### BRIEF DESCRIPTION OF THE DRAWINGS

FIG. 1 is a plan view illustrating a semiconductor device in accordance with an embodiment of the present disclosure.

FIGS. 2A and 2B are cross-sectional views illustrating the semiconductor device in accordance with an embodiment of the present disclosure.

FIGS. 3A to 14C are plan views and cross-sectional views illustrating a method for fabricating a semiconductor device in accordance with an embodiment of the present disclosure.

### DETAILED DESCRIPTION

Exemplary embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

Hereinafter, the various embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also instances in which a third layer exists between the first layer and the second layer or the substrate.

The embodiments in accordance with the disclosure reduce the difficulty of the bit line process by first forming the storage node contact pad and reducing the etching height of the bit line.

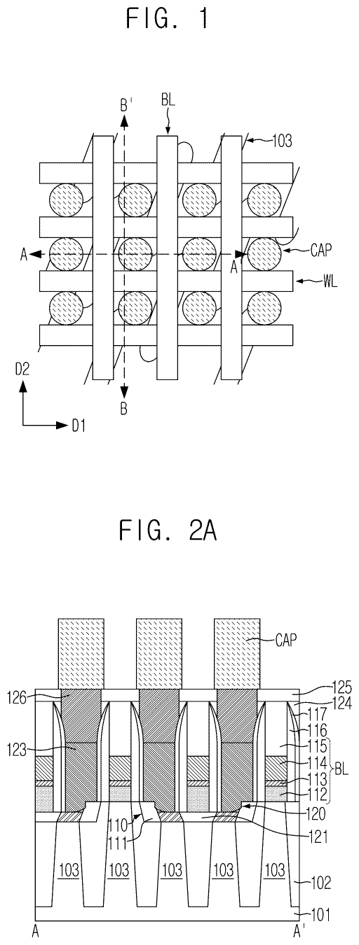

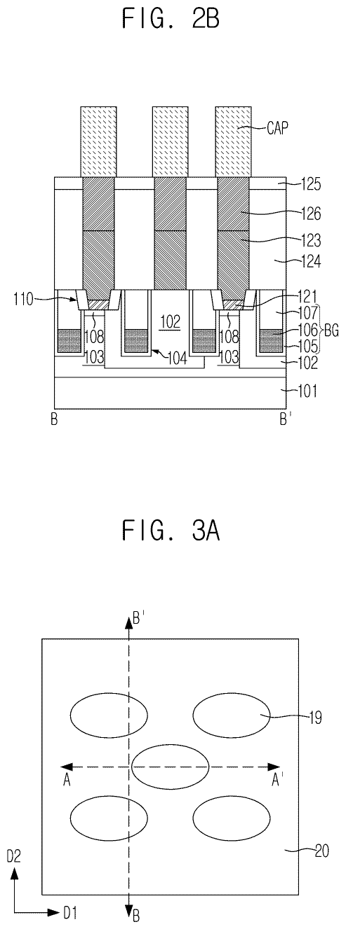

FIG. 1 is a plan view illustrating a semiconductor device in accordance with an embodiment of the present disclosure. FIGS. 2A and 2B are cross-sectional views illustrating the semiconductor device in accordance with the embodiment of the present disclosure. FIG. 2A is a cross-sectional view taken along a line A-A′ shown in FIG. 1, and FIG. 2B is a cross-sectional view taken along a line B-B′ shown in FIG. 1. FIG. 1 shows the positional relationship of each constituent element on a plane, and mainly illustrates a word line and a bit line.

Referring to FIGS. 1, 2A, and 2B, the semiconductor device may include a plurality of memory cells. Each memory cell may include conductive structures that are disposed at different levels. For example, each memory cell may include a cell transistor including a buried word line WL, a bit line BL, and a memory element CAP.

An isolation layer 102 and an active region 103 may be formed in a substrate 101. A plurality of active regions 103 may be defined by the isolation layer 102. Each active region 103 may be of a bar shape having a long axis and a short axis. The active regions 103 may be disposed to be spaced apart from each other at a predetermined interval.

The substrate 101 may be formed of a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as germanium. The substrate 101 may also include a III/V-group semiconductor substrate, for example, a compound semiconductor substrate, such as gallium arsenide (GaAs). The substrate 101 may also include an SOI (Silicon-On-Insulator) substrate.

A line-shaped buried word line WL extending in a first direction D1 may be formed in the substrate 101. The buried word line WL may be formed as a buried gate structure.

The buried gate structure BG may include a gate dielectric layer 105 formed on a surface of a gate trench 104, a gate electrode 106 formed over the gate dielectric layer 105 to fill the gate trench 104, and a gate capping layer 107.

To be specific, a line-shaped gate trench 104 crossing the active region 103 and the isolation layer 102 in the first direction D1 may be formed in the substrate 101. The bottom surface of the gate trench 104 may be disposed at a higher level than the bottom surface of the isolation layer 102. In other words, the gate trench 104 may have a shallower depth than the isolation layer 102. According to another embodiment of the present disclosure, the bottom portion of the gate trench 104 may have a curvature. According to another embodiment of the present disclosure, the isolation layer 102 in a direction that the gate trench 104 extends may be etched to a predetermined depth to form a fin in the active region 103.

A gate dielectric layer 105 may be formed on the surface of the gate trench 104. A gate electrode 106 filling a portion of the gate trench 104 may be formed over the gate dielectric layer 105. A gate capping layer 107, which may also be called a sealing layer, may be formed over the gate electrode 106 to fill the remaining portion of the gate trench 104. The top surface of the gate capping layer 107 may be disposed at the same level as the top surface of the substrate 101. The top surface of the gate electrode 106 may be disposed at a lower level than the top surface of the substrate 101. The gate electrode 106 may include a low-resistance metal material. The gate electrode 106 may include a combination of at least one or more among a metal material, a metal nitride, and polysilicon, or a stacked structure thereof. For example, the gate electrode 106 may be formed by sequentially stacking titanium nitride and tungsten. According to another embodiment of the present disclosure, the gate electrode 106 may be formed of titanium nitride only (TiN-Only). According to another embodiment of the present disclosure, the gate electrode 106 may include a stacked structure of a metal material and polysilicon.

An impurity region 108 may be formed in the substrate 101. The impurity region 108 may be referred to as a ‘source and drain (source/drain) region’. The impurity region 108 may be formed in the substrate 101 contacting the bit line structure BL and the substrate 101 contacting the contact pad 121, individually.

A bit line structure BL may be formed over the substrate 101. The bit line structure BL may include a stacked structure of a bit line 112, 113, and 114 and a bit line hard mask 115.

The bit line structure BL may be of a line type that extends in a second direction D2 which is orthogonal to the first direction D1. Both of the first and second directions D1 and D2 may be horizontal directions that are parallel to the surface of the substrate 101. The bit line structures BL may be disposed to be spaced apart from each other in the first direction D1. The bit line 112 may directly contact the substrate 101, specifically, the active region 103.

The bit line 112, 113 and 114 may include a stacked structure of first to third conductive lines 112, 113 and 114. The first to third conductive lines 112, 113 and 114 may include different materials, respectively. For example, the first conductive line 112 may include polysilicon. For example, the polysilicon may include doped polysilicon. The second and third conductive lines 113 and 114 may include a metal material. The conductive line hard mask 115 may include a dielectric material.

First and second bit line spacers 116 and 117 may be formed on the sidewall of the bit line structure BL. The first and second bit line spacers 116 and 117 may include a dielectric material. The first and second bit line spacers 116 and 117 may include a stacked structure of different dielectric materials. For example, the first and second bit line spacers 116 and 117 may include one or more selected from a group including silicon nitride, silicon oxide, silicon oxynitride, and a low-k material, or a combination thereof. According to another embodiment of the present disclosure, the first and second bit line spacers 116 and 117 may include a single layer or a multi-layer structure of three or more layers. According to yet another embodiment of the present disclosure, the bit line spacer may further include an air gap.

A storage node contact 123 may be disposed between the neighboring conductive structures. The storage node contact 123 may have a pillar shape. Each of the storage node contacts 123 may be disposed to be spaced apart from each other by an isolation dielectric layer (not shown). The storage node contact 123 may be disposed over the contact pad 121. The contact pad 121 may electrically couple the storage node contact 123 to the substrate 101, that is, the active region 103. The bottom surface of the contact pad 121 may be disposed at a lower level than the bottom surface of the bit line structure BL. The storage node contact 123 may extend below the top surface of the substrate 101. In other words, the bottom surface of the storage node contact 123 may be disposed at a lower level than the top surface of the substrate 101. The storage node contact 123 may include a conductive material. For example, the conductive material may include a semiconductor material or a metal material. For example, the semiconductor material may include polysilicon. For example, the metal material may include tungsten (W). According to another embodiment of the present disclosure, the storage node contact 123 may include a stacked structure of a semiconductor material and a metal material. According to yet another embodiment of the present disclosure, the storage node contact 123 may include a stacked structure of a semiconductor material, an ohmic contact layer, and a metal material.

The contact pad 121 may improve the contact margin between the storage node contact 123 and the substrate 101. The contact pad 121 may include a conductive material. For example, the contact pad 121 may include polysilicon. For example, the polysilicon may include doped polysilicon. The contact pad 121 may serve to electrically connect the storage node contact 123 to the substrate 101. The contact pad 121 may be referred to as a ‘storage node contact pad 121’.

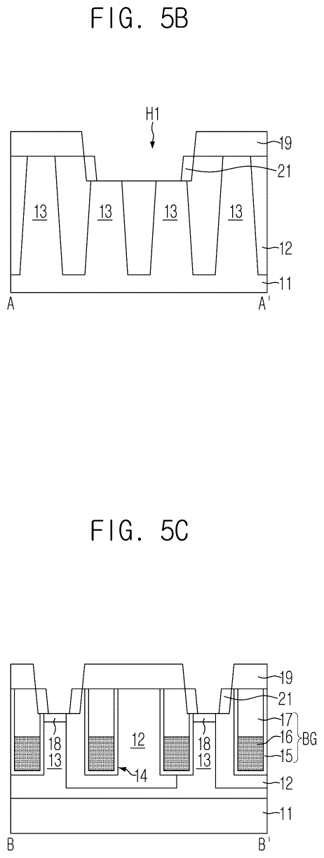

One side of the contact pad 121 may contact a contact spacer 111, and the other side of the contact pad 121 may contact a first isolation dielectric layer 120. The contact spacer 111 may be formed between the neighboring bit line structures BL that are adjacent to the contact pad 121. The contact spacer 111 may be formed in an oval ring type or an oval doughnut type, as illustrated in FIG. 5A. The contact spacer 111 may be applied to space the contact pad 121 and the bit line structure BL apart from each other. The contact spacer 111 may include a dielectric material. For example, the contact spacer 111 may include silicon nitride, but the concept and spirit of the present disclosure are not limited thereto.

The contact pads 121 may be formed symmetrically with one bit line structure BL interposed therebetween. The first isolation dielectric layer 120 may be formed between the neighboring contact pads 121. The first isolation dielectric layer 120 may serve to isolate the neighboring contact pads 121 from each other. The first isolation dielectric layer 120 may include a dielectric material. The first isolation dielectric layer 120 may include a low-k oxide. For example, the dielectric material may include silicon oxycarbide (SiCO), but the concept and spirit of the present disclosure are not limited thereto. According to another embodiment of the present disclosure, the dielectric material may include silicon nitride.

The storage node contact 123 may be formed between the neighboring bit line structures BL. The storage node contact 123 may be coupled to the impurity region 108 through the contact pad 121.

The storage node contact 123 may have an island shape that is disposed to be spaced apart from other storage node contacts 123 in the first and second directions D1 and D2. The storage node contact 123 may be disposed to be spaced apart from each other in the first direction D1 by the bit line structure BL. The storage node contacts 123 may be disposed to be spaced apart from each other in the second direction D2 by a second isolation dielectric layer 124.

A landing pad 126 may be formed over the storage node contact 123. The landing pad 126 may overlap with the storage node contact 123. The landing pad 126 may electrically connect the storage node contact 123 to the upper memory element CAP. An inter-layer dielectric layer 125 may be formed between the landing pads 126. In other words, the landing pads 126 may be spaced apart from each other by the inter-layer dielectric layer 125. The landing pads 126 may include a conductive material.

According to another embodiment of the present disclosure, the landing pad 126 may overlap with a portion of the storage node contact 123.

The memory element CAP may be formed over the landing pad 126. The memory element CAP may include a capacitor including a storage node. The storage node may include a pillar shape, but the concept and spirit of the present disclosure are not limited thereto. Although not illustrated, a dielectric layer and a plate node may be further formed over the storage node. The storage node may also have a cylindrical shape in addition to the pillar shape.

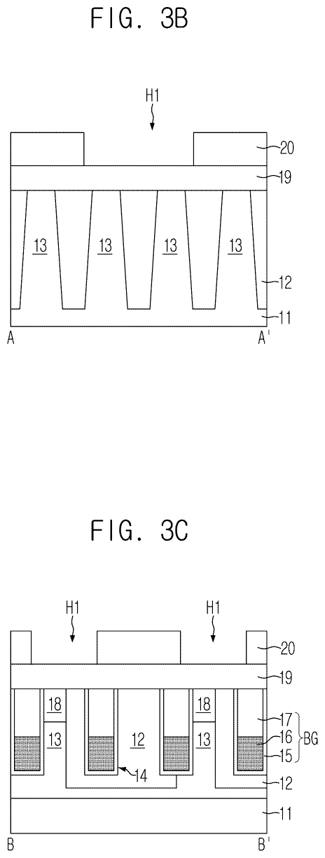

FIGS. 3A to 14C are plan views and cross-sectional views illustrating a method for fabricating a semiconductor device in accordance with an embodiment of the present disclosure. FIGS. 3A, 4A, 5A, 6A, 7A, 8A, 9A, 10A, 11A, 12A, 13A, and 14A are plan views illustrating the semiconductor device of each process step. FIGS. 3B, 4B, 5B, 6B, 7B, 8B, 9B, 10B, 11B, 12B, 13B, and 14B are cross-sectional views taken along a line A-A′ shown in FIGS. 3A, 4A, 5A, 6A, 7A, 8A, 9A, 10A, 11A, 12A, 13A, and 14A, respectively. FIGS. 3C, 4C, 5C, 6C, 7C, 8C, 9C, 10C, 11C, 12C, 13C, and 14C are cross-sectional views taken along a line B-B′ shown in FIGS. 3A, 4A, 5A, 6A, 7A, 8A, 9A, 10A, 11A, 12A, 13A, and 14A, respectively. To help understanding and explanation, the plan view and cross-sectional views of the same process step will be described together.

Referring to FIGS. 3A to 3C, an isolation layer 12 may be formed over a substrate 11. An active region 13 may be defined by the isolation layer 12. As shown in FIG. 1, each active region 13 may be of a bar shape having a long axis and a short axis. Each active region 13 may be disposed to be spaced apart from other active regions 13 at a predetermined interval.

The isolation layer 12 may be formed by a shallow trench isolation (STI) process. The STI process may be as follows:

First, the substrate 11 may be etched to form an isolation trench (whose reference numeral is omitted). The isolation trench may be filled with a dielectric material to form an isolation layer 12. The isolation layer 12 may include silicon oxide, silicon nitride, or a combination thereof. Chemical vapor deposition (CVD) or another deposition process may be performed to fill the isolation trench with the dielectric material. A planarization process such as chemical mechanical polishing (CMP) may be additionally performed.

Subsequently, a buried gate structure BG may be formed in the substrate 11. The buried gate structure BG may have a line shape extending in the first direction D1. The buried gate structure BG may be referred to as a ‘buried word line structure’. The buried gate structure BG may include a gate trench 14, a gate dielectric layer 15 covering the bottom surface and sidewalls of the gate trench 14, a gate electrode 16 filling a portion of the gate trench 15 over the gate dielectric layer 15, and a gate capping layer 17 formed over the gate electrode 16.

A method for forming the buried gate structure BG may be as follows:

First, the gate trench 14 may be formed in the substrate 11. The gate trench 14 may have a line shape crossing the active region 13 and the isolation layer 12. The gate trench 14 may be formed by forming a mask pattern (not shown) over the substrate 11 and performing an etching process with the mask pattern used as an etching mask. The gate trench 14 may be formed to be shallower than the isolation trench. In other words, the bottom surface of the gate trench 14 may be disposed at a higher level than the bottom surface of the isolation layer 12. The depth of the gate trench 14 may be sufficiently deep to make a large average cross-sectional area of the gate electrode 16. Accordingly, the resistance of the gate electrode 16 may be reduced. According to another embodiment of the present disclosure, the bottom edges of the gate trench 14 may have a curvature. By forming the bottom edges of the gate trench 14 to have a curvature, the unevenness at the bottom of the gate trench 14 may be minimized, and thus, the filling of the gate electrode 16 may be easily performed.

According to another embodiment of the present disclosure, after the gate trench 14 is formed, a fin region may be formed. The fin region may be formed by recessing a portion of the isolation layer 12.

Subsequently, a gate dielectric layer 15 may be formed on the bottom surface and sidewalls of the gate trench 14. Before the gate dielectric layer 15 is formed, etching damage on the surface of the gate trench 14 may be cured. For example, a sacrificial oxide may be formed by a thermal oxidation process, and then the sacrificial oxide may be removed.

The gate dielectric layer 15 may be formed by a thermal oxidation process. For example, the bottom surface and sidewalls of the gate trench 14 may be oxidized to form the gate dielectric layer 15.

According to another embodiment of the present disclosure, the gate dielectric layer 15 may be formed by a deposition method, such as chemical vapor deposition (CVD) or atomic layer deposition (ALD). The gate dielectric layer 15 may include a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, and a combination thereof. Other known high-k materials may be selectively used as the high-k material.

According to another embodiment of the present disclosure, the gate dielectric layer 15 may be formed by depositing a liner polysilicon layer and then radical-oxidizing the liner polysilicon layer.

According to yet another embodiment of the present disclosure, the gate dielectric layer 15 may be formed by forming a liner silicon nitride layer and then radical-oxidizing the liner silicon nitride layer.

Subsequently, the gate electrode 16 may be formed over the gate dielectric layer 15. To form the gate electrode 16, a conductive layer (not shown) may be formed to fill the gate trench 14, and then a recessing process may be performed. The recessing process may be performed by performing an etch-back process, or sequentially performing a chemical mechanical polishing (CMP) process and an etch-back process. The gate electrode 16 may have a recessed shape that fills a portion of the gate trench 14. In other words, the top surface of the gate electrode 16 may be disposed at a lower level than the top surface of the substrate 11. The gate electrode 16 may include a metal, a metal nitride, or a combination thereof. For example, the gate electrode 16 may be formed of titanium nitride (TiN), tungsten (W), or a stack of titanium nitride/tungsten (TiN/W). The titanium nitride/tungsten (TiN/W) stack may be a structure in which titanium nitride is conformally formed and then a portion of the gate trench 14 is filled with tungsten. Titanium nitride may be used alone as the gate electrode 16, which may be referred to as a gate electrode 16 of a ‘TiN-only’ structure. According to another embodiment of the present disclosure, the gate electrode 16 may include a stacked structure of a metal and polysilicon.

Subsequently, the gate capping layer 17 may be formed over the gate electrode 16. The gate capping layer 17 may include a dielectric material. The remaining portion of the gate trench 14 over the gate electrode 16 may be filled with the gate capping layer 17. The gate capping layer 17 may include silicon oxide. According to yet another embodiment of the present disclosure, the gate capping layer 17 may have a Nitride-Oxide-Nitride (NON) structure. The top surface of the gate capping layer 17 may be disposed at the same level as the top surface of the substrate 11. To this end, a chemical mechanical polishing (CMP) process may be performed using the top surface of the substrate 11 as an etch stop target when the gate capping layer 17 is formed.

After the buried gate structure is formed as described above, an impurity region 18 may be formed in the substrate 11 between the buried gate structures. The impurity region 18 may be formed by a doping process such as implantation. The impurity region 18 may be individually formed in the region to which the bit line contact is to be coupled and the region to which the storage node contact is to be coupled. Although the cross-sectional view of this embodiment of the present disclosure shows only the impurity region of the region to which the storage node contact is to be coupled, the impurity region of the region to which the bit line contact is to be coupled may also be formed at the same time.

A cell transistor of a memory cell may be formed by the gate electrode 16 and the impurity region 18.

Subsequently, a passivation layer 19 and a hard mask pattern 20 may be sequentially formed over the substrate 11. The passivation layer 19 may include a dielectric material. For example, the passivation layer 19 may include silicon oxide, but the concept and spirit of the present disclosure are not limited thereto.

The hard mask pattern 20 may include a material having an etching selectivity with respect to the passivation layer 19. The hard mask pattern 20 may include, for example, silicon nitride, but the concept and spirit of the present disclosure are not limited thereto. The hard mask pattern 20 may be formed through a series of processes of forming a hard mask material over the passivation layer 19, forming a mask pattern defining an opening H1 over the hard mask material, and then etching the hard mask material by using the mask pattern.

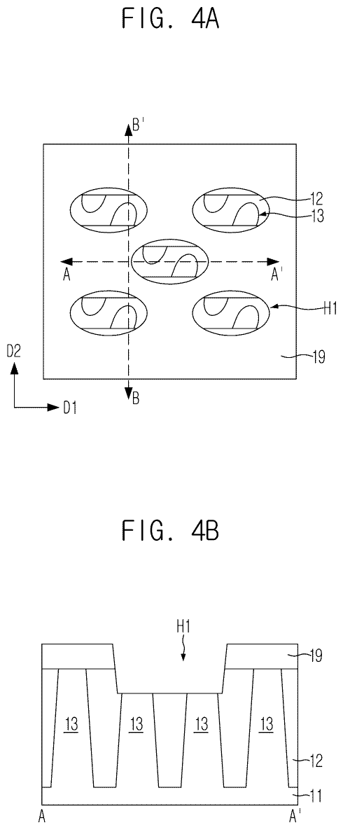

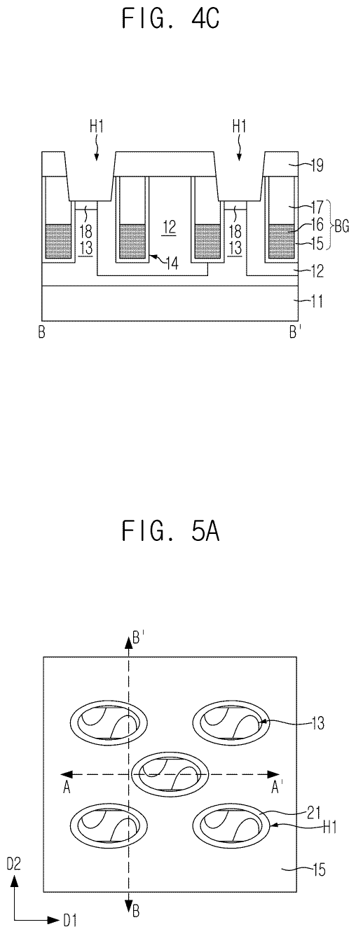

Referring to FIGS. 4A to 4C, the opening H1 may be formed. The opening H1 may be formed through a series of processes of etching the passivation layer 19, the isolation layer 12, and the active region 13 to a predetermined depth by using the hard mask pattern 20.

The opening H1 may have an oval shape. The opening H1 may expose the ends of two neighboring active regions 13 at the same time. The ends of the active regions 13 exposed by the opening H1 may be storage node regions. The opening H1 may be formed using an Extreme Ultraviolet (EUV) mask, but the concept and spirit of the present disclosure are not limited thereto.

As the active region 13 and the isolation layer 12 in the opening H1 are etched, the top surfaces of the active region 13 and the isolation layer 12 in the opening H1 may be protected by the passivation layer 19 and may be disposed at a lower level than the top surfaces of the active region 13 and the isolation layer 12 of the unetched portion. The active region 13 of the storage node region may be exposed by the opening H1.

Referring to FIGS. 5A to 5C, a contact spacer 21 may be formed on the sidewall of the isolation layer 12 of the opening H1.

The contact spacer 21 may be formed through a series of processes of depositing a dielectric material on the profile of the resultant structure including the opening H1 and spacer-etching the dielectric material. For example, the dielectric material may include silicon nitride, but the concept and spirit of the present disclosure are not limited thereto.

According to another embodiment of the present disclosure, after the contact spacer 21 is formed, the substrate 11 exposed in the opening H1 may be additionally etched.

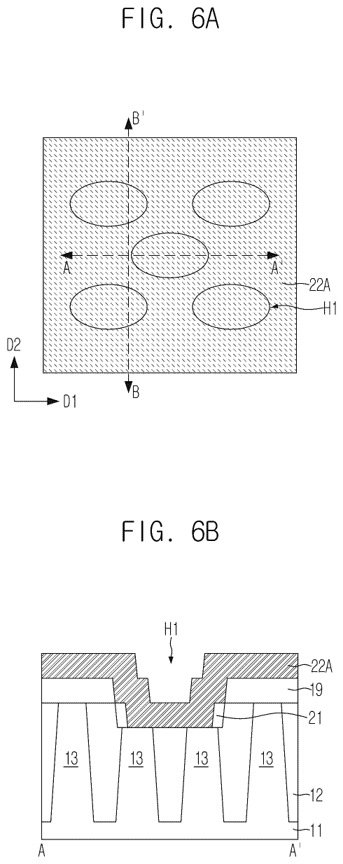

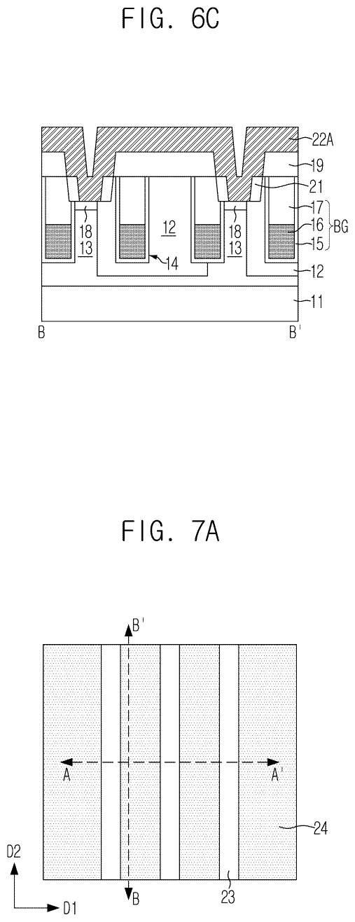

Referring to FIGS. 6A to 6C, a conductive material 22A may be formed along the profile of the opening H1 including the contact spacer 21. The conductive material 22A may be formed through a deposition process. For example, the conductive material 22A may include polysilicon. For example, the polysilicon may include doped polysilicon.

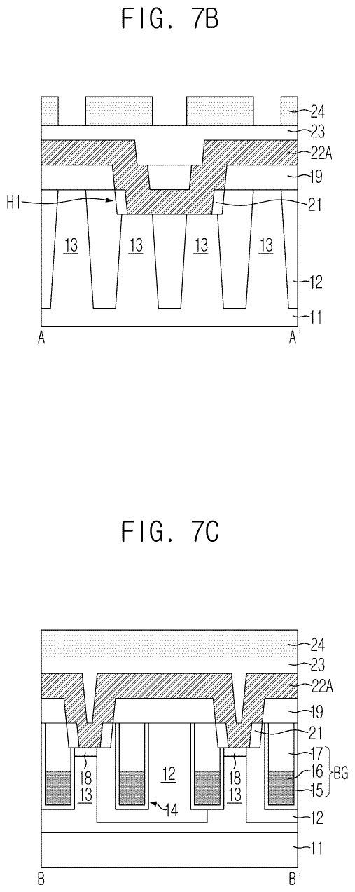

Referring to FIGS. 7A to 7C, a sacrificial layer 23 may be formed over the conductive material 22A.

The sacrificial layer 23 may be a planarization layer. The sacrificial layer 23 may include a dielectric material. For example, the dielectric material may include a spin-on-dielectric (SOD) or a spin-on-carbon (SOC).

Subsequently, a mask pattern 24 defining a bit line region may be formed over the sacrificial layer 23.

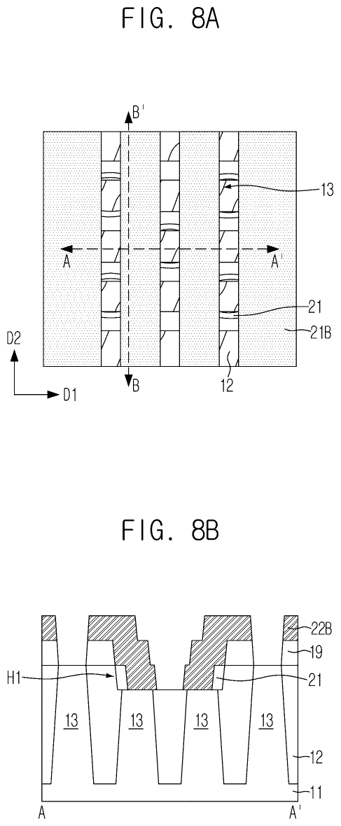

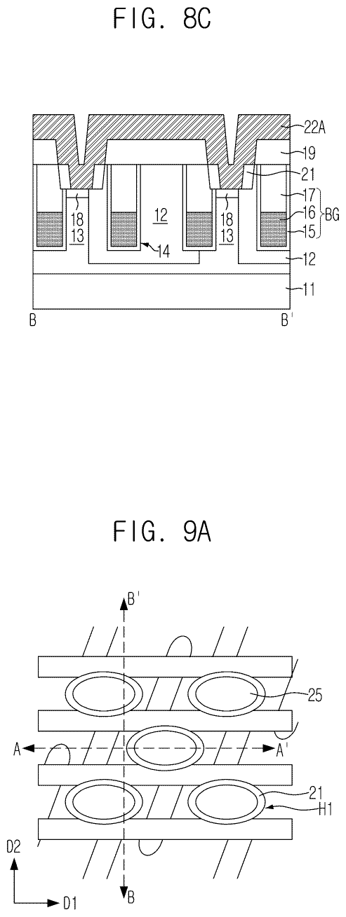

Referring to FIGS. 8A to 8C, the active region 13 of the bit line region may be exposed.

To this end, the sacrificial layer 23 and the conductive material 22A (see FIG. 7B) may be sequentially etched by using the mask pattern 24 (see FIG. 7B). The etched conductive material may be indicated by a reference numeral ‘22B’. The contact spacer 21 may not be etched due to the etching selectivity. Therefore, the contact spacer 21 may still maintain an oval ring shape or an oval doughnut shape.

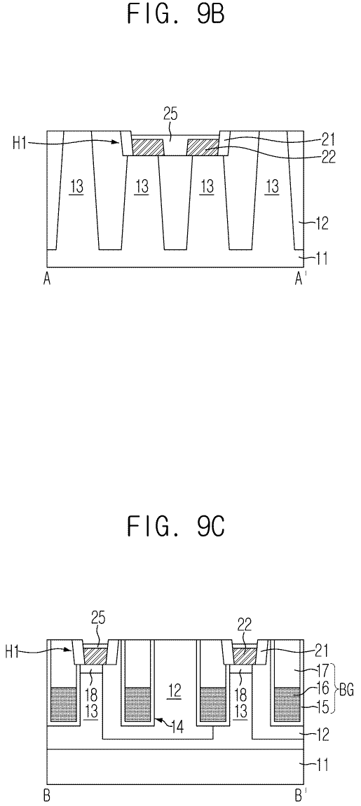

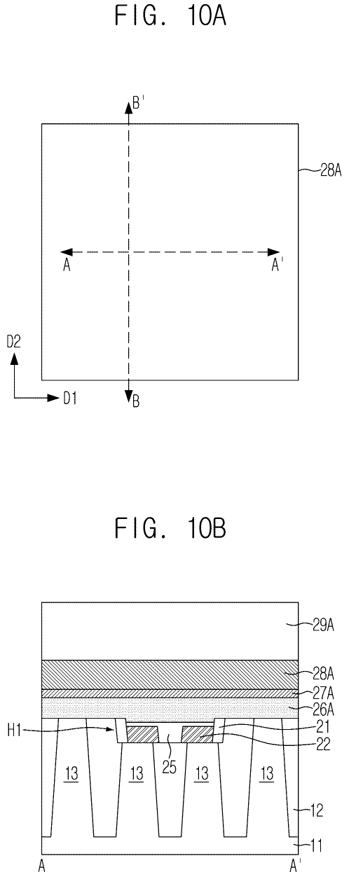

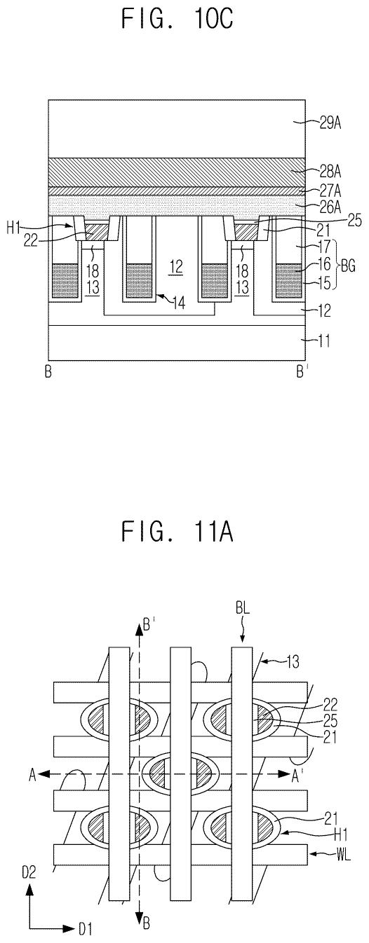

Referring to FIGS. 9A to 9C, the contact pad 22 may be formed.

The contact pad 22 may be formed by etching back the etched conductive material 22B (see FIG. 7B). The top surface of the contact pad 22 may be disposed at a lower level than the top surface of the substrate 11. The top surface of the contact pad 22 may be disposed at a lower level than the top surface of the contact spacer 21.

Referring to FIG. 9B, a bit line region may be disposed between the neighboring contact pads 22.

Subsequently, a first isolation dielectric layer 25 may be formed over the contact pad 22 and the isolation layer 12 in the opening H1.

The first isolation dielectric layer 25 may serve to isolate the neighboring contact pads 22 and to insulate the contact pad 22 and the bit line, which will be formed through a subsequent process. The first isolation dielectric layer 25 may be formed through a series of processes of forming a dielectric material over the substrate 11 including the contact pad 22 and then etching back the dielectric material to remain in the opening 16. The top surface of the first isolation dielectric layer 25 may be disposed at a lower level than the top surface of the substrate 11. Referring to FIG. 9A, the first isolation dielectric layer 25 may remain in an oval shape in the opening H1.

The first isolation dielectric layer 25 may include a material having an etching selectivity with respect to the substrate 11. In other words, the first isolation dielectric layer 25 may include a material having an etching selectivity with respect to a silicon material. Also, the first isolation dielectric layer 25 may include a low-k material. Here, the low-k material may refer to a material having a lower dielectric constant than that of silicon nitride (Si₃N₄). The low-k material may include a material having a dielectric constant which is lower than approximately 3.9. For example, the first isolation dielectric layer 25 may include SiCO, but the concept and spirit of the present disclosure are not limited thereto. According to another embodiment of the present disclosure, the first isolation dielectric material 21A may include silicon nitride or silicon oxide.

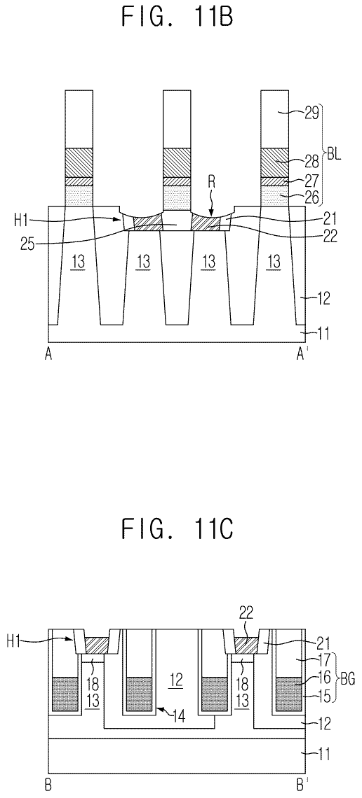

Referring to FIGS. 10A to 10C, the first to third conductive line materials 26A, 27A, and 28A may be sequentially formed over the first isolation dielectric layer 25 and the substrate 11.

For example, the first conductive line material 26A may include polysilicon. For example, the polysilicon may include doped polysilicon. The bottom surface of the first conductive line material 26A in the opening H1 may be disposed at a lower level than the top surface of the substrate 11. The first conductive line material 26A in the opening H1 may be spaced apart from the contact pad 22 by the first isolation dielectric layer 25.

The second and third conductive line materials 27A and 28A may include a metal-containing material. The second and third conductive line materials 27A and 28A may include a metal, a metal nitride, a metal silicide, or a combination thereof.

Subsequently, a hard mask material 29A may be formed over the third conductive line material 28A. The hard mask material 29A may include a dielectric material having an etching selectivity with respect to the first to third conductive line materials 26A, 27A, and 28A. For example, the hard mask material 29A may include silicon nitride, but the concept and spirit of the present disclosure are not limited thereto.

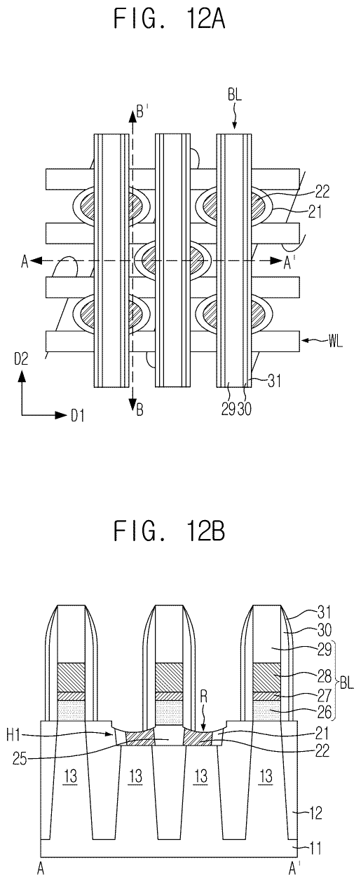

Referring to FIGS. 11A to 11C, a bit line structure BL may be formed. The bit line structure BL may include a stacked structure of first to third conductive lines 26, 27, and 28 and a bit line hard mask 29.

To this end, a mask pattern may be formed over a hard mask material 29A (see FIG. 11B), and the hard mask material 29A and third to first conductive lines 28A, 27A, and 26A may be sequentially etched by using the mask pattern.

Subsequently, a recess R exposing the contact pads 22 on both sides of the bit line structure BL may be formed in the opening H1. The first isolation dielectric layer 25 and the contact spacer 22 exposed together with the contact pads 22 may also be partially lost. As shown in FIG. 11C, when the recess R is formed (shown in 11B), the first isolation dielectric layer 25 over the contact pads 22 may be removed.

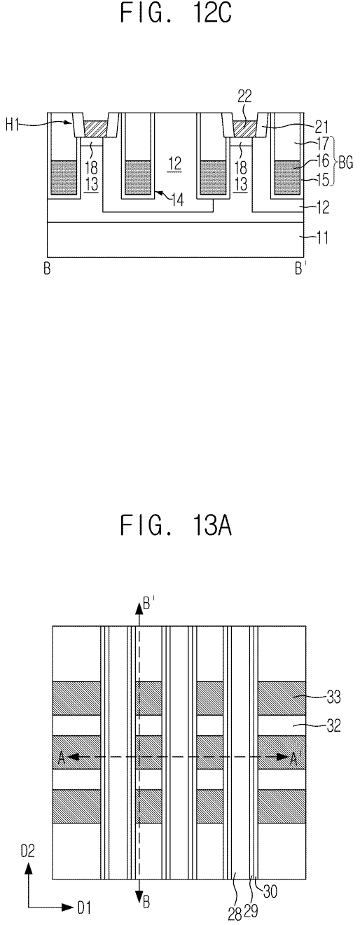

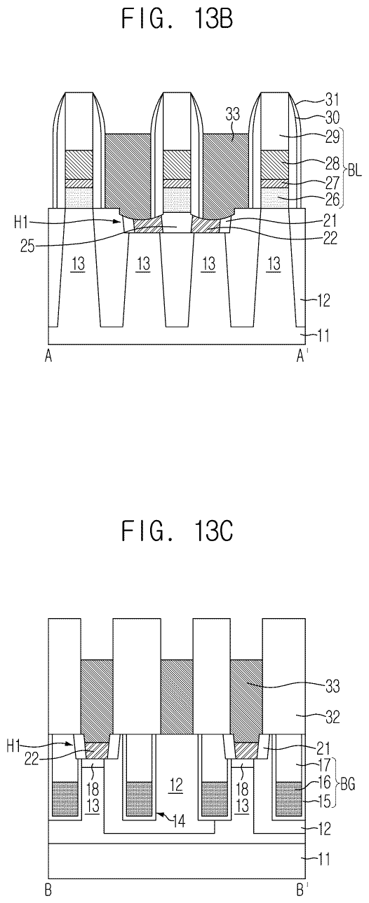

Referring to FIGS. 12A to 12C, the first and second bit line spacers 30 and 31 may be sequentially formed on both sidewalls of the bit line structure BL. Each of the first and second bit line spacers 30 and 31 may include one selected from the group including silicon nitride, silicon oxide, silicon oxynitride, and a low-k material. For example, the low-k material may include SiCO. According to another embodiment of the present disclosure, each of the first and second bit line spacers 30 and 31 may include a multi-layer structure. According to another embodiment of the present disclosure, one among the first and second bit line spacers 30 and 31 may further include a low-k material or an air gap.

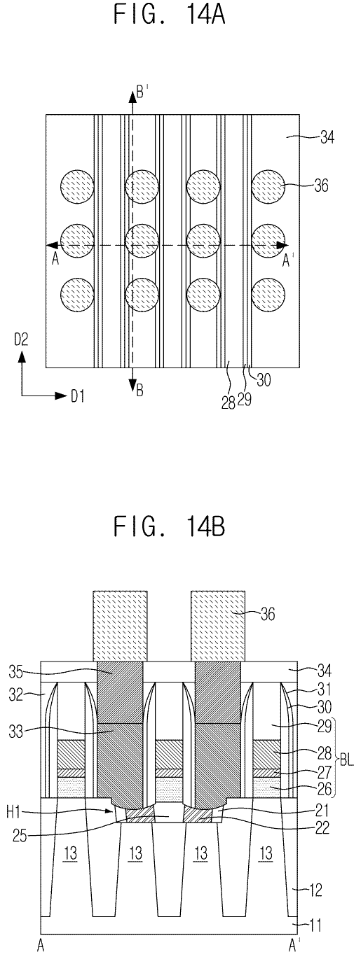

Referring to FIGS. 13A to 13C, a storage node contact 33 may be formed between the neighboring conductive line structures BL. The shape of the storage node contact 33 may include a pillar shape. The storage node contacts 33 may be disposed to be spaced apart from each other by the conductive line structure BL in the first direction D1. The storage node contacts 33 may be disposed to be spaced apart from each other by the second isolation dielectric layer 32 in the second direction D2. The second isolation dielectric layer 32 may include silicon oxide or silicon nitride.

The storage node contact 33 may be formed through a series of processes of gap-filling a contact conductive material between the neighboring bit line structures BL, forming an isolation portion by patterning the contact conductive material into a pillar shape, and then gap-filling the isolation portion with the second isolation dielectric layer 32.

According to another embodiment of the present disclosure, the storage node contact 33 may be formed through a series of processes of gap-filling the space between the neighboring bit line structures BL with a dielectric material, forming a contact area where the contact pad 22 is exposed by patterning the dielectric material into a pillar shape, and then gap-filling the contact area with a conductive material.

The storage node contact 33 may include a conductive material. For example, the conductive material may include a semiconductor material or a metal material. For example, the semiconductor material may include polysilicon. For example, the metal material may include tungsten (W). According to another embodiment of the present disclosure, the storage node contact 33 may include a stacked structure of a semiconductor material and a metal material. According to yet another embodiment of the present disclosure, the storage node contact 33 may include a stacked structure of a semiconductor material, an ohmic contact layer, and a metal material.

The top surface of the storage node contact 33 may be disposed at a lower level than the top surface of the bit line structure BL. The bottom surface of the storage node contact 33 may directly contact the contact pad 22. The storage node contact 33 may be coupled to the substrate 11 by the contact pad 22.

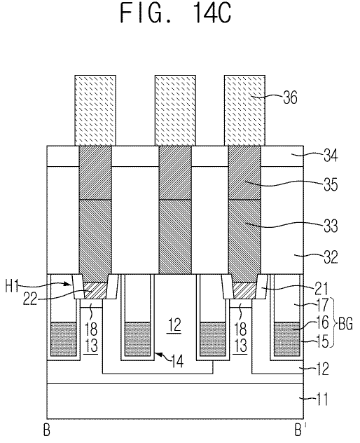

Referring to FIGS. 14A to 14C, a landing pad 35 may be formed over the storage node contact 33.

The landing pad 35 may be formed through a series of processes of forming an inter-layer dielectric layer 34 over the bit line structure BL including the storage node contact 33, forming an opening that exposes at least a portion of the storage node contact 29 by etching a portion of the inter-layer dielectric layer 34 and the second isolation dielectric layer 32, and then gap-filling the opening with a conductive material.

According to another embodiment of the present disclosure, the storage node contact 33 may be formed in a multi-layer structure.

According to yet another embodiment of the present disclosure, the landing pad 35 may overlap with a portion of the storage node contact 33.

Subsequently, a memory element 36 may be formed over the landing pad 35.

The memory element 36 may include a capacitor including a storage node. The storage node may include a pillar shape, but the concept and spirit of the present disclosure are not limited thereto. Although not illustrated, a dielectric layer and a plate node may be further formed over the storage node. The storage node may also have a cylindrical shape in addition to the pillar shape. According to another embodiment of the present disclosure, the landing pad 35 may be omitted.

As described above, according to the embodiment of the present disclosure, the bit line contact for coupling the bit line structure BL and the substrate 11 to each other may be omitted, and the etching margin may be secured by decreasing the etching height of the bit line structure BL. Also, according to the embodiment of the present disclosure, the landing margin between the storage node contact 33 and the substrate 11 may be improved by forming the contact pad 22 that is coupled to the memory element 36 first.

According to the embodiment of the present disclosure, there is an effect of reducing the process difficulty of a bit line and securing a space where a storage node contact may be formed.

According to the embodiment of the present disclosure, there is an effect of improving the landing margin between the storage node contact and the substrate by forming a contact pad first.

According to the embodiment of the present disclosure, there is an effect of improving cell characteristics and securing mass productivity by improving a resistance.

While the present disclosure has been described with respect to the specific embodiments, it will be apparent to those skilled in the art that various changes and modifications may be made without departing from the spirit and scope of the invention as defined in the following claims.

What is claimed is:

1. A semiconductor device, comprising:
a semiconductor substrate;
neighboring bit line structures spaced apart from each other over the semiconductor substrate;
at least one contact pad formed in the semiconductor substrate between the neighboring bit line structures and having a bottom surface which is lower than a bottom surface of the neighboring bit line structures; and
a storage node contact, disposed over the at least one contact pad, contacting the at least one contact pad.

2. The semiconductor device of claim 1, wherein each of the neighboring bit line structures includes a bit line and a bit line hard mask, and
the bit line directly contacts the semiconductor substrate.

3. The semiconductor device of claim 1, wherein the at least one contact pad comprises neighboring contact pads, further comprising:
an isolation dielectric layer between the semiconductor substrate, and one of the neighboring bit line structures between the neighboring contact pads.

4. The semiconductor device of claim 3, wherein the isolation dielectric layer includes one selected from among silicon oxycarbide (SiCO), silicon nitride, and silicon oxide.

5. The semiconductor device of claim 1, further comprising:
a contact spacer on a first sidewall of the at least one contact pad.

6. The semiconductor device of claim 5, wherein the contact spacer includes silicon nitride.

7. The semiconductor device of claim 5, wherein the contact spacer has an oval ring shape or an oval doughnut shape.

8. The semiconductor device of claim 1, further comprising:
a landing pad over the storage node contact; and
a memory element formed over the landing pad and coupled to the landing pad.

9. The semiconductor device of claim 8, wherein the landing pad overlaps with at least a portion of the storage node contact.

10. The semiconductor device of claim 1, wherein the at least one contact pad includes polysilicon.

11. The semiconductor device of claim 1, wherein a top surface of the storage node contact is disposed at a lower level than a top surface of the bit line structure.

12. The semiconductor device of claim 1, further comprising:
a buried gate structure in the substrate.
